(19) United States
(12) Patent Application Publication
(10) Pub. No.: US 2005/0230081 A1
(43) Pub. Date: Oct. 20, 2005

(54) Heat dissipation device and manufacturing method thereof

(75) Inventor: Jung-An Lin, Hsin Tien City (TW)

Correspondence Address: BIRCH STEWART KOLASCH & BIRCH, PO BOX 747, FALLS CHURCH, VA, 22040-0747, US

(73) Assignee: VIA TECHNOLOGIES, INC.

(21) Appl. No.: 10/960,935

(22) Filed: Oct. 12, 2004

(30) Foreign Application Priority Data
Apr. 20, 2004 (TW) 093111011

(51) Int. Cl. H05K 7/20

(52) U.S. Cl. 165/80.3; 361/704

(57) ABSTRACT

A heat dissipation device is made by skived-fin technology and has a thermal conductive portion and a plurality of fins. The fins are integrally formed with the thermal conductive portion. Each of the fins has a plurality of through holes, a top portion, and a bottom portion. The bottom portion of each fin connects with the thermal conductive portion with a curve. The thermal conductive portion, which is disposed on the bottom of the heat dissipation device, is integrally formed with the fins in one metal board.

### BACKGROUND OF THE INVENTION

1. Field of the Invention

The present invention relates to a heat dissipation device and a manufacturing method thereof, and particularly to a heat dissipation device and a manufacturing method thereof using skived-fin technology for thermal dissipation of high-power chip.

2. Description of Prior Art

As the density of an IC (integrated circuit) increases, the chip of information product produces more heat, and the temperature of the chip is usually over the maximum temperature limit. In particular, the operating speed and the processing function of the CPU (central processing unit) are increasing continually. Without proper heat dissipation, the components run the risk of damage, even to the point of interrupting the host.

To solve the heat dissipation problem of the chip, a heat dissipation device with multiple fins is usually mounted on the chip. The conventional art is shown in FIG. 1. A heat dissipation device 9 has a rectangular base board 91 and a plurality of fins 92 which are extending from the base board 91. The heat dissipation device 9 is made of high thermal conductive material. When the temperature of a chip 8 rises, the fins 92 of the heat dissipation device 9 will conduct heat to the surrounding air. Then the heat is dissipated into the air through air convection, as indicated by arrow A in FIG. 1.

The conventional fin installation method employs the technique of extrusion with the metal, aluminum. This method is most economical; however, the thickness of the fins and the spacings therebetween are wider, such that it usually does not meet the heat generating rate of a high-power chip, and does not dissipate heat sufficiently.

Another fin installation method assembles a plurality of fins on the base board by bonding or soldering. Although this method increases the number of fins and thus the heat dissipation area of the heat dissipation device, the conductive efficiency between the base board and the fins is also limited because the base board and the fins are not connected directly.

Moreover, the fins 92 of the conventional heat dissipation device 9 are arranged closely for increasing the heat dissipation area and heat dissipation capability. Each spacing 93 between the fins 92 is relatively very narrow (about 1.5 mm). Such structure becomes a huge obstacle when guiding cool air to the surrounding of the fins. FIG. 2 illustrates a cross-sectional view of air convection around fins along line 2-2 of FIG. 1. Because the shape of fins are rectangular, so they tend to form invisible walls. When the outside cool air flows close to the surrounding of the fins 92, the air forks and is guided upwardly by the external shape of the fins 92, (shown as arrow B in FIG. 2). Therefore, the bottom portion of the fins 92 which is adjacent to the chip 8 cannot get enough cool air for heat dissipation. The operation of the chip is possibly interrupted because the heat can not be dissipated efficiently.

According to the above mentioned prior art, there are other improved conventional arts. For example, the cross-section of fins can be changed to an inverted trapezium, or the fins can be sliced into plural thin rods for increasing air convection. However, the fins are arranged too tightly, and the narrow spacing between the fins of the above heat dissipation device causes other problems. For example, the velocity of the air convention at the bottom of the spacing is low because the airflow turns, and results in dust being deposited on the bottom portion of the spacing. The deposited dust will reduce the heat dissipation rate, and it is hard to remove because of the tight fins. Further, the life-span of the heat dissipation device is shortened.

### SUMMARY OF THE INVENTION

The present invention provides a heat dissipation device and manufacturing method thereof, which particularly reduces the total weight thereof and provides good thermal conductivity for reducing costs and increasing efficiency.

The present invention provides a heat dissipation device and a manufacturing method thereof that improves air convection rate and reduces dust accumulation therein, for quicker heat dissipation and a longer life-span.

The present invention provides a manufacturing method of a heat dissipation device comprising the following steps. A metal board formed with a plurality of through channels is provided. A planer tool is provided for skiving the metal board along a predetermined oblique angle and cutting off a first metal piece. The metal board is skived along the same predetermined oblique angle to produce a metal slice and the metal slice is erected to form a fin. The previous step is repeated to produce a predetermined number of fins. A last metal block is cut off.

A heat dissipation device according to the present invention, which is made by skived-fin technology, comprises a thermal conductive portion and a plurality of fins. The fins are integrally formed with the thermal conductive portion. Each fin has a plurality of through holes, a top portion and a bottom portion. Each of the bottom portions extends in a curve from the base portion and perpendicular to the thermal conductive portion.

### BRIEF DESCRIPTION OF THE DRAWINGS

Other objects, advantages, and novel features of the present invention will become more apparent from the following detailed description when taken in conjunction with the accompanying drawings, in which:

FIG. 1 is a perspective view illustrating a heat dissipation device according to the prior art;

FIG. 2 is a perspective view illustrating the air convection in the heat dissipation device along a line 2-2 of FIG. 1;

FIG. 3 is a perspective view of a metal board and a planer tool according to the present invention;

FIG. 4 is a perspective view of a metal board before being skived according to the present invention;

FIG. 5 is a perspective view of a metal board after being skived according to the present invention;

FIG. 6 illustrates a perspective view of a metal board after being skived and erecting a metal slice according to the present invention;

FIG. 7 illustrates a perspective view of the heat dissipation device of first embodiment according to the present invention;

FIG. 8 illustrates a perspective view of the metal board of second embodiment according to the present invention after being cut off;

FIG. 9 illustrates a perspective view of the metal board of second embodiment according to the present invention is skived and erects a metal slice;

FIG. 10 illustrates a perspective view of the heat dissipation device of second embodiment according to the present invention assembled on a PCB and mounted with a fan; and

FIG. 11 illustrates a cross-sectional view along a line 11-11 in FIG. 10.

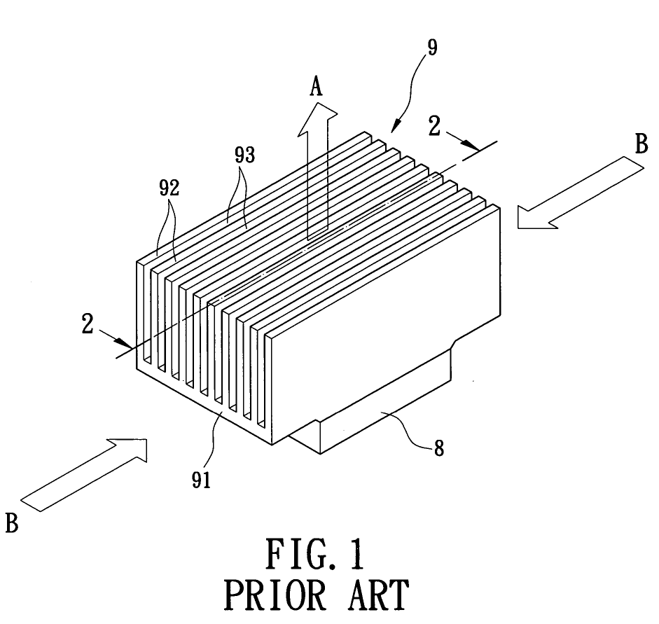

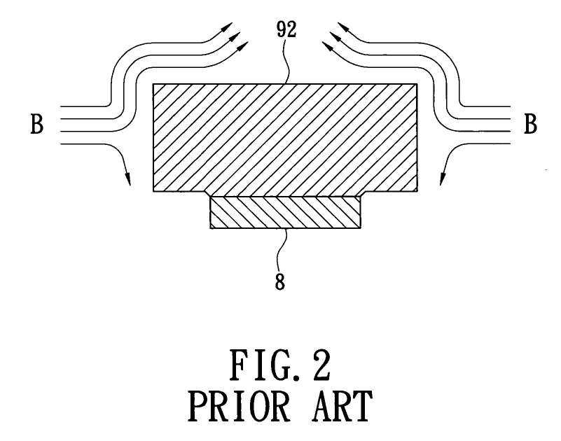

### DETAILED DESCRIPTION OF THE INVENTION

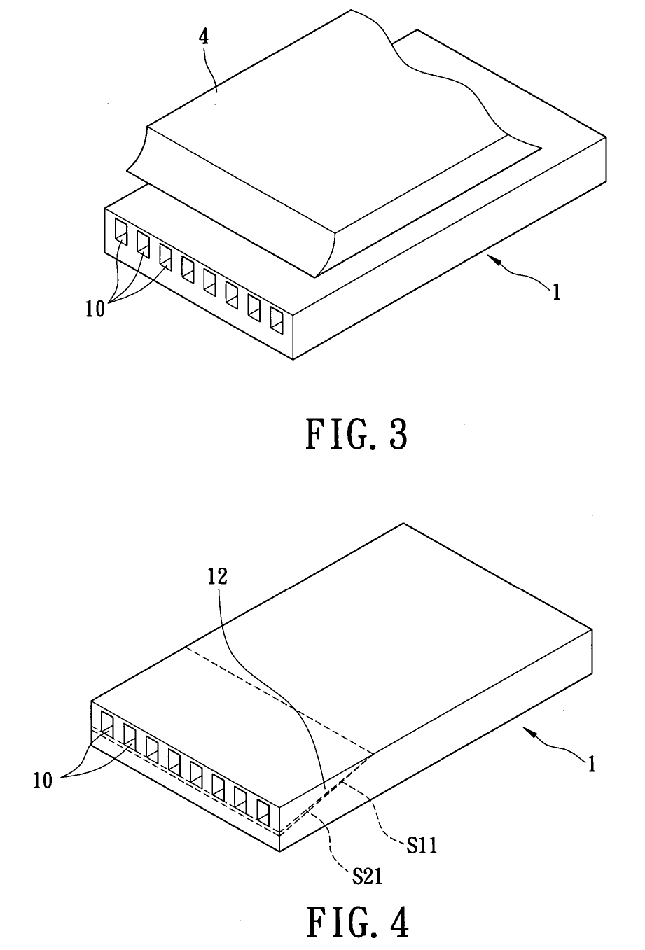

FIGS. 3 through 6 illustrate the manufacturing processes according to the present invention of a heat dissipation device and a manufacturing method thereof. The present invention first provides a metal board 1. The metal board 1 can be an aluminum ingot or a metal block made of other metal material, such as copper. The metal board 1 is formed with a plurality of through channels 10. The channels 10 are formed integrally during extrusion of the metal board when the metal board 1 is made of aluminum. Because the copper has a boiling point higher than that of aluminum, it is hard to use extruding technology. The channels 10 can be formed by further processing the metal board 1 when the metal board 1 is made of copper. The shape of the channels is not limited, and can be, for example, a circle, a rectangle with arc-corns, or a rectangle as shown in FIG. 3.

A planer tool 4 with a hardness exceeds the metal board is provided for skiving the metal board 1, which is called skived-fin technology. The planer tool 4 is usually installed in a CNC (computer numerical control) lathe, and is controlled precisely by a computer. In the skiving processes, the metal board 1 is fixed by a fixing tool. Then, as shown in FIG. 4, a first metal piece 12 is cut off along a line S11 with a predetermined oblique angle. In this embodiment, the first metal piece 12 is skived to a portion under the channels 10 (along the line S11), or is skived to a bottom edge of the channels 10 along a line S21 as shown in FIG. 4. The first metal piece 12 also can be skived to a portion above a bottom edge of the channels 10.

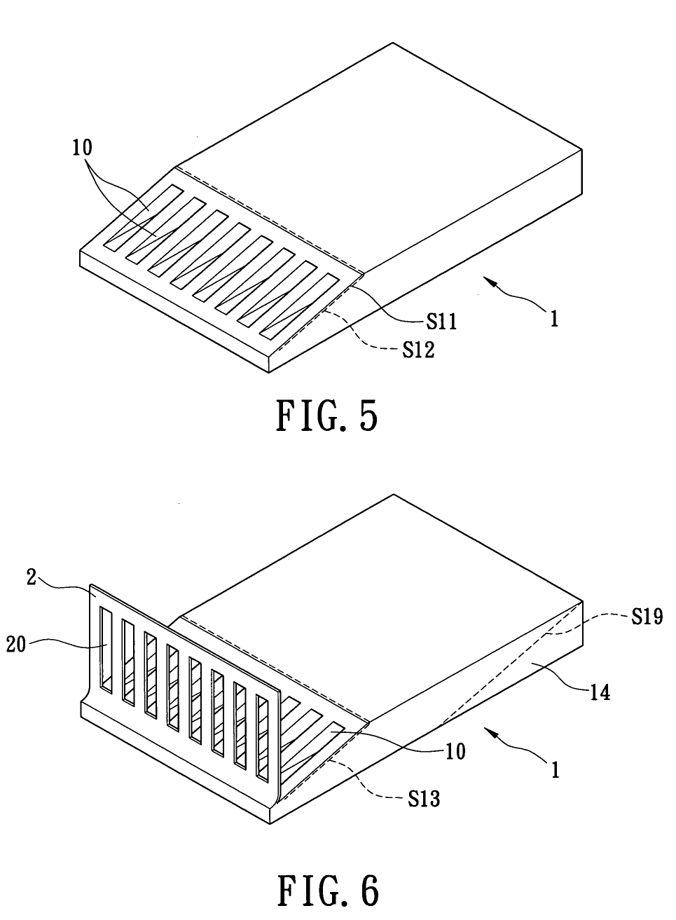

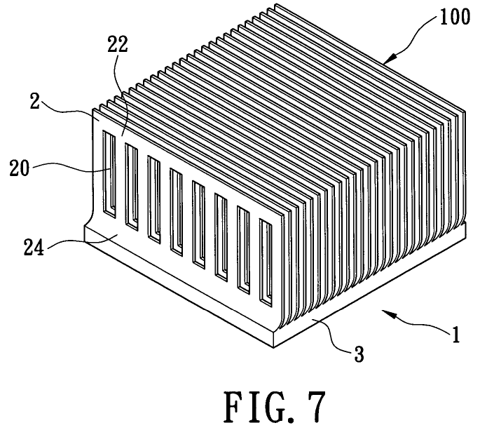

Reference is made to FIG. 5. The metal board 1 is skived along another line S12, which is parallel to the line S11 (with the same predetermined oblique angle), to produce a metal slice and the metal slice is erected to form a fin 2. Referring to FIG. 6, the fin 2 is connected to the metal board 1 without breaking off. The above steps, skiving and erecting a metal slice, i.e. skiving another metal slice along another line S13 (having the same oblique angle with S11), are repeated until a predetermined number of fins is produced or until a last metal slice is reached. Then, a surplus last metal block 14 is cut off.

Reference is made to FIG. 7, which illustrates a perspective view of the heat dissipation device of first embodiment according to the present invention, By the above-mentioned steps, a heat dissipation device 100 according to the present invention is shown. The heat dissipation device 100 has a thermal conductive portion 3 and a plurality of fins 2 which are integrally formed with the thermal conductive portion 3. Each of the fins 2 has a plurality of through holes 20, a top portion 22 and a bottom portion 24. The through holes 20 are long and parallel to each other, and are formed from the channels 10 during skiving processes.

Each of the bottom portions 24 extends in a curve from the thermal conductive portion 3 and perpendicular to the thermal conductive portion 3. The through holes 20 of the fins 2 not only reduce the total weight, but also enhance air convention and lateral air can therefore flow through the heat dissipation device 100, especially for the inner fins 2. The reduced weight, which is estimated according to the volume of the channels 10 of the metal board 1, the first metal piece 12, and the last metal block 14, is about 20% less than that of the original metal board 1. It can reduce costs, and has better air convention.

The heat dissipation device 100 has a large surface area, because the skived-fin technology can reduce the thickness of the fins 2 to 0.25-0.8 mm. The spacing between the fms 2 can be reduced to 0.5 mm. The height of the fins 2 can reach 50-60 mm. Moreover, the manufacturing method enhances heat conduction, not using soldering or molding technology which has higher thermal resistance, to ensure that the thermal conductive portion 3 and the fins 2 have good thermal conduction therebetween.

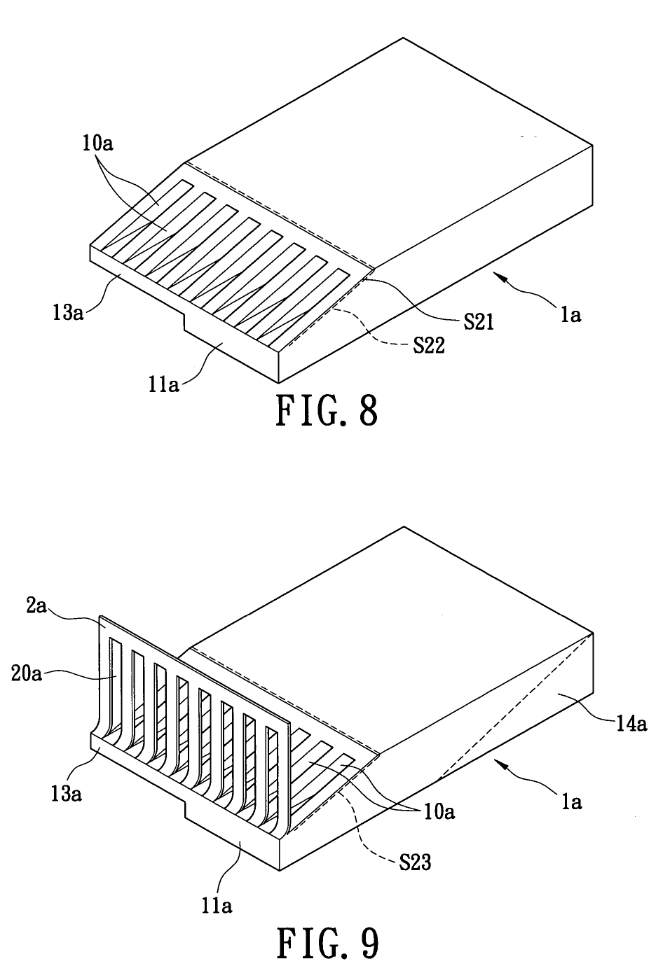

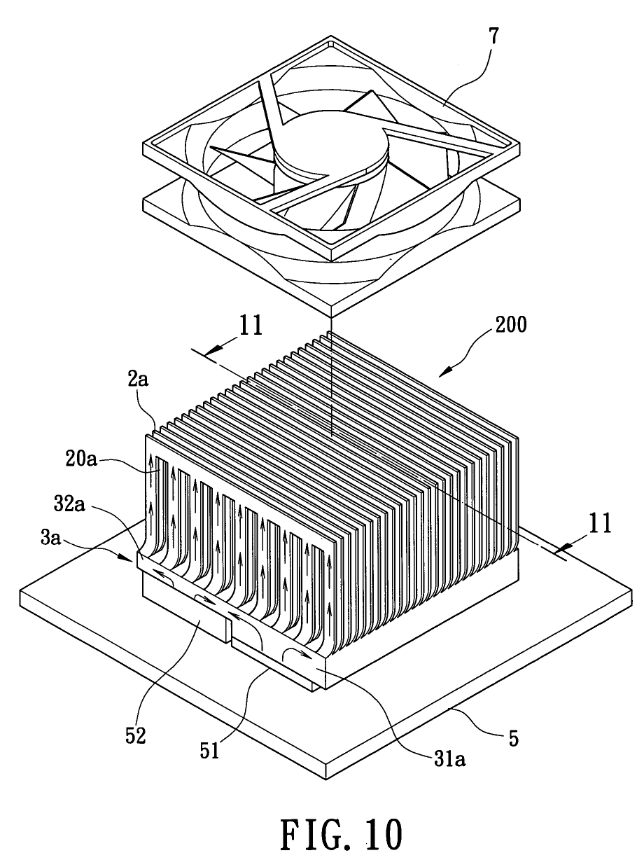

Referring to FIGS. 8 to 10, a heat dissipation device and manufacturing method thereof of another embodiment according to the present invention is illustrated. A metal board 1a has a base portion, which is formed integrally with a first base portion 11a and a second base portion 13a with different heights during extruding. The metal board 1a is skived along the line S21 with the predetermined oblique angle in FIG. 4. The line S21 is skived to bottom edges of channels 10a. It can be skived to above the bottom edges of the channels 10a. Referring to FIG. 8, then a metal slice is then skived along a line S22, which is parallel to the line S21, and the metal slice is erected to form the fins 2a as illustrated in FIG. 9. The above step of skiving the metal slice is repeated until a last metal block 14a is cut off, and a heat dissipation device 200 of second embodiment according the present invention is shown in FIG. 10.

Referring to FIG. 10, the heat dissipation device 200 has a thermal conductive portion 3a and a plurality of fins 2a, which are integrally formed with the thermal conductive portion 3a. Each of the fins 2a has a plurality of through holes 20a connecting with the thermal conductive portion 3a. The thermal conductive portion 3a is formed with a first thermal conductive portion 31a and a second thermal conductive portion 32a, which are formed from the first base portion 11a and the second base portion 13a of the metal board 1. The heat dissipation device 200 therefore can be disposed on two adjacent chips 51, 52 of a PCB 5. In this embodiment, the through holes 20a not only avoid the dust deposited on bottom portion of the fins 2a, but also are profitable for cleaning the fins 2a. By blowing downwardly on the fins 2a with strong airflow, the dust between the fins 2a will be cleansed easily via the through holes 20a. It is more beneficial for smooth airflow if the heat dissipation device 200 further assembled with a fan 7.

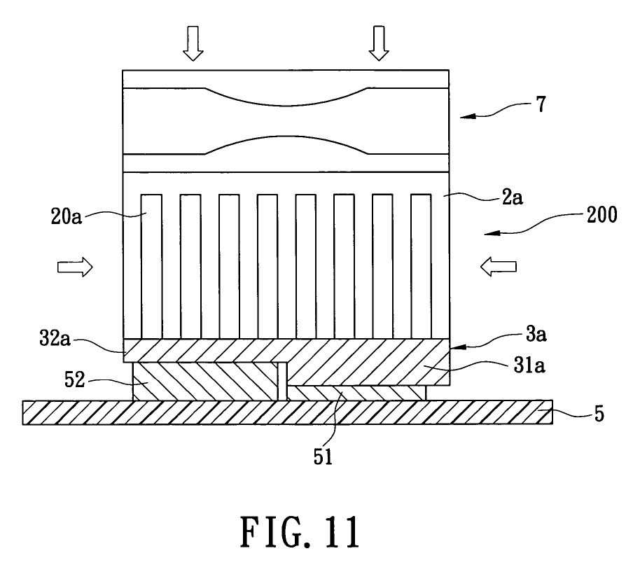

Reference is made to FIG. 11, which illustrates a cross-sectional view along a line 11-11 in FIG. 10. The fan 7 can produce downward airflows and guide side airflow passing between the fins 2a of the heat dissipation device 200, and air is exhausted speedily and smoothly via the through holes 20a. The heat dissipation device 200 of the present invention not only utilizes the side airflows without stagnation, but also generates a smoother airflow without deposition of dust between the fins 20a. In particular, the problem of the turned airflow with low speed is resolved, as well as the problem of dust deposited on the bottom of the fins.

The performance of a heat dissipation device depends on the density of the fins, heat dissipation area, and thermal conductivity, so that the heat dissipation device and manufacturing method thereof according to the present invention are better than those of the conventional heat dissipation devices made by, for example, molding or embedding technology. The skived-fin heat dissipation device is more adaptable for high-level computers than conventional heat dissipation devices.

The fins of the heat dissipation device according to the present invention are very thin, and the number thereof is increased much more than conventional heat dissipation device. The design saves material cost and provides a much smoother airflow. The present invention has a good cooling effect without needing a fan, and is thus adaptable to a chip on a PCB, which needs to save power.

The present invention has been simulated with the following conditions: size is 80×60×35 mm, power is 7 W, a heat source with size of 35×35×16 mm. Comparing structures with and without through holes, the fins with through holes have a significantly improved effect.

Thereby, the present invention providing the heat dissipation device and manufacturing method thereof by skived-fin technology and simultaneously forming through holes for air convention has advantages as followed:

1. The heat dissipation device according to the present invention has more fins in a unit length, and increased thermal dissipation area.

2. The heat dissipation device according to the present invention can reduce material use by about ⅕ to reduce the production cost greatly.

3. The heat dissipation device according to the present invention has the thermal conductive portion and the fins formed on a same metal board integrally, without the problem of indirect connection, thus providing better thermal conduction.

4. The through holes of the heat dissipation device according to the present invention guide airflow to flow between the fins, thus more effectively removing heat and dust.

It is to be understood, however, that even though numerous characteristics and advantages of the present invention have been set forth in the foregoing description, together with details of the structure and function of the invention, the disclosure is illustrative only, and changes may be made in detail, especially in matters of shape, size and arrangement of parts within the principles of the invention to the full extent indicated by the broad general meaning of the terms in which the appended claims are expressed.

1. A manufacturing method for a heat dissipation device, comprising the steps of:
forming a plurality of through channels in a metal board;
skiving the metal board along a predetermined oblique angle and cutting off a first metal piece;
skiving the metal board along the same predetermined oblique angle to produce a metal slice and erecting the metal slice to form a fin;
repeating said above step and skiving to produce a plurality of fins; and
cutting off a last metal block.

2. The manufacturing method of heat dissipation device as in claim 1, wherein the channels are formed integrally when extruding the metal board, and wherein the metal board is made of aluminum.

3. The manufacturing method of heat dissipation device as in claim 1, wherein the channels are formed by an additional process, and wherein the metal board is made of copper.

4. The manufacturing method of heat dissipation device as in claim 1, wherein the channels of the metal board have a rectangular cross-section with arc-corns.

5. The manufacturing method of heat dissipation device as in claim 1, wherein the metal board is formed with a first base portion and a second base portion with different heights on a bottom thereof during extruding.

6. The manufacturing method of heat dissipation device as in claim 1, wherein the channels are formed by an additional process performed on the metal board.

7. The manufacturing method of heat dissipation device as in claim 1, wherein the skiving steps are performed by a planer tool.

8. The manufacturing method of heat dissipation device as in claim 7, wherein the planer tool is installed in a CNC (computer numerical control) lathe.

9. The manufacturing method of heat dissipation device as in claim 1, wherein the first metal piece is skived to a portion below the channels.

10. The manufacturing method of heat dissipation device as in claim 1, wherein the first metal piece is skived to a bottom edge of the channels.

11. The manufacturing method of heat dissipation device as in claim 1, wherein the first metal piece is skived to a portion above a bottom edge of the channels.

12. A heat dissipation device made by skived-fin technology, comprising:
a thermal conductive portion; and
a plurality of fins integrally formed with the thermal conductive portion, wherein each fin has a plurality of through holes, a top portion and a bottom portion, and each of the bottom portions extends in a curve from the thermal conductive portion and perpendicular to the thermal conductive portion.

13. The heat dissipation device as in claim 12, wherein the thermal conductive portion is formed with a first thermal conductive portion and a second thermal conductive portion with different heights, and the heat dissipation device is thereby disposed on two adjacent chips of a PCB.

14. The heat dissipation device as in claim 12, wherein a bottom of the through hole is at a predetermined distance from the thermal conductive portion.

15. The heat dissipation device as in claim 12, wherein a bottom of the through hole is connected with the thermal conductive portion.

16. The heat dissipation device as in claim 12, wherein the through hole of the fin is a slender rectangle in shape.

17. The heat dissipation device as in claim 12, wherein the through hole of the fin is a slender ellipse in shape.

18. The heat dissipation device as in claim 12, wherein each of the fins has a thickness of 0.25 to 0.8 mm.

19. The heat dissipation device as in claim 12, wherein the heat dissipation device is assembled with a fan thereon.
